(19) United States
(12) Patent Application Publication
(10) Pub. No.: US 2004/0159874 A1
(43) Pub. Date: Aug. 19, 2004

(54) Semiconductor device

(76) Inventors: Takamichi Tsuchiya, Yokohama-shi (JP); Moto Yabuki, Tokyo (JP)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 10/635,574

(22) Filed: Aug. 7, 2003

(30) Foreign Application Priority Data
Aug. 8, 2002 (JP) 2002-231094

(51) Int. Cl. H01L 29/76; H01L 21/8242

(52) U.S. Cl. 257/306; 438/244; 257/751; 438/627

(57) ABSTRACT

Disclosed is a semiconductor device comprising an insulating film, a capacitor formed on the insulating film and comprising a bottom electrode, a top electrode, and a dielectric film between the top electrode and the bottom electrode, a plug passing through the insulating film and connected to the bottom electrode, and an oxygen barrier film covering the capacitor and the insulating film, and having lower oxygen permeability than the insulating film.

### CROSS-REFERENCE TO RELATED APPLICATIONS

This application is based upon and claims the benefit of priority from the prior Japanese Patent Application No. 2002-231094, filed Aug. 8, 2002, the entire contents of which are incorporated herein by reference.

### BACKGROUND OF THE INVENTION

1. Field of the Invention

The present invention relates to a semiconductor device having a capacitor.

2. Description of the Related Art

Recently, nonvolatile memories, for example, ferroelectric random access memories (FeRAM), have been developed using a ferroelectric film, such as Pb(Zr, Ti)O₃ (PZT), as the dielectric film of a capacitor. Such a ferroelectric memory is known to use a capacitor-on-plug (COP) structure in which a bottom electrode of a capacitor is formed on a plug.

However, when the COP structure is used, a major problem occurs: the plug is oxidized during an annealing step. The manufacturing process for a ferroelectric memory includes an annealing step for crystallizing a ferroelectric film or recovering damage during capacitor processing. Since the annealing is performed in an atmosphere containing oxygen, the plug is oxidized, increasing the resistance of the plug and contact resistance thereof.

Oxygen is diffused into the plug conceivably by two routes: one is through the ferroelectric film; and the other is though an insulating film formed immediately below the bottom electrode. To prevent the oxygen diffusion in the first case, a material acting as an effective oxygen barrier is used to form the bottom electrode. However, no effective means has been developed against the second case, which is a major cause of oxidization of the plug.

As described above, the oxidization of a plug has been a serious problem in a ferroelectric memory having a COP structure. However, no effective means has been developed against the oxidization in the prior art, thereby decreasing the characteristics and reliability of devices.

### BRIEF SUMMARY OF THE INVENTION

According to a first aspect of the present invention, there is provided a semiconductor device comprising: an insulating film; a capacitor formed on the insulating film and comprising a bottom electrode, a top electrode, and a dielectric film between the top electrode and the bottom electrode; a plug passing through the insulating film and connected to the bottom electrode; and an oxygen barrier film covering the capacitor and the insulating film, and having lower oxygen permeability than the insulating film.

According to a second aspect of the present invention, there is provided a semiconductor device comprising: an insulating film; a capacitor formed on the insulating film and comprising a bottom electrode, a top electrode, and a dielectric film between the top electrode and the bottom electrode; a plug passing through the insulating film and connected to the bottom electrode; and an oxygen barrier film formed between the insulating film and the plug, and having lower oxygen permeability than the insulating film.

According to a third aspect of the present invention, there is provided a semiconductor device comprising: an insulating film; a capacitor formed on the insulating film and comprising a bottom electrode, a top electrode, and a dielectric film between the top electrode and the bottom electrode; a plug passing through the insulating film and connected to the bottom electrode; a first oxygen barrier film covering the capacitor and the insulating film, and having lower oxygen permeability than the insulating film; and a second oxygen barrier film formed between the insulating film and the plug, and having lower oxygen permeability than the insulating film.

### BRIEF DESCRIPTION OF THE SEVERAL VIEWS OF THE DRAWING

FIG. 1 is a schematic sectional view of a semiconductor device according to a first embodiment of the present invention;

FIG. 2 is a schematic sectional view of a semiconductor device according to a modified example of a first embodiment of the present invention;

FIG. 3 is a schematic sectional view of a semiconductor device according to a second embodiment of the present invention;

FIGS. 4A to 4D are schematic sectional views of parts of a semiconductor device in a manufacturing step according to a second embodiment of the present invention; and

FIG. 5 is a schematic sectional view of a semiconductor device according to a third embodiment of the present invention.

### DETAILED DESCRIPTION OF THE INVENTION

Embodiments of the present invention will be explained with reference to the accompanying drawings.

(First Embodiment)

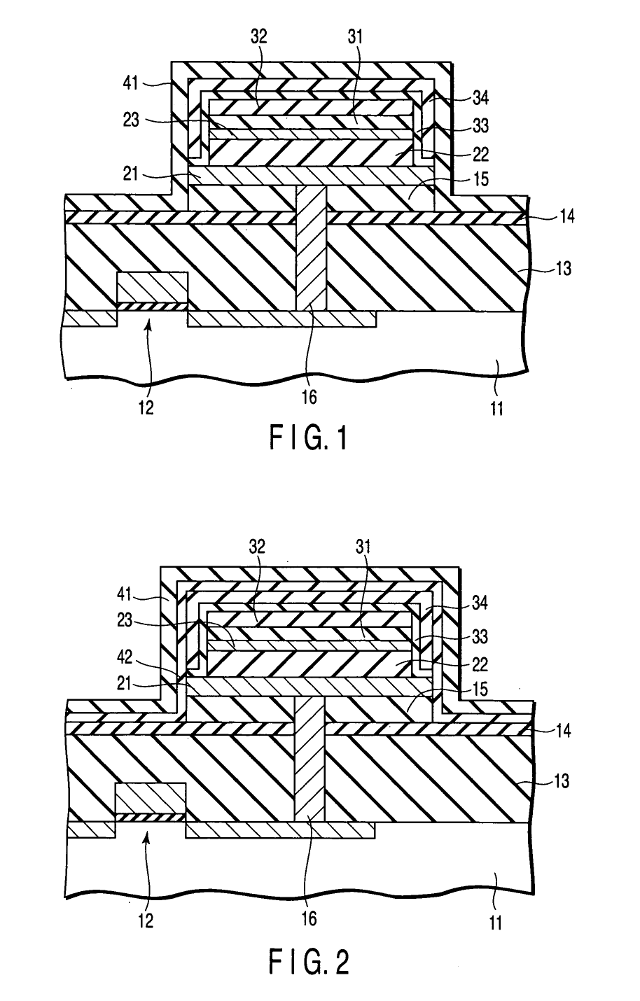

FIG. 1 is a schematic sectional view showing a structure of a semiconductor device, which is a ferroelectric memory having a COP structure, according to a first embodiment of the present invention.

On a semiconductor substrate 11 such as a silicon substrate, an MIS transistor 12 is formed, and an interlayer insulating film 13 (such as a silicon oxide film using TEOS) is formed so as to cover the MIS transistor 12.

On the interlayer insulating film 13, an oxygen barrier film 14 is formed. On the oxygen barrier film 14, an insulating film 15 (underlying insulating film formed under a capacitor) is formed. As the oxygen barrier film 14, use is made of a silicon nitride film formed by low pressure CVD (LPCVD). As the insulating film 15, use is made of a silicon oxide film formed of TEOS by LPCVD.

To one of the source and drain of the transistor 12, a plug 16 is connected. The plug 16 passes through the interlayer insulating film 13, the oxygen barrier film 14, and the insulating film 15, and comes into contact with a bottom electrode 21 of the capacitor. The plug 16 is formed of a conductive material such as tungsten (W) or polysilicon.

The capacitor (ferroelectric capacitor) comprises a bottom electrode 21, a ferroelectric film 22 formed on the bottom electrode 21, and a top electrode 23 formed on the ferroelectric film 22. As the bottom electrode 21 and the top electrode 23, use is made of an iridium (Ir) film or an iridium oxide (IrO₂) film. These materials are very effective barriers to oxygen. The bottom electrode 21, since it is formed of an effective material as an oxygen barrier, can suppress diffusion of oxygen from the ferroelectric film 22 to the plug 16. The ferroelectric film 22 is formed of, for example, Pb(Zr,Ti)O₃ (PZT).

On the top electrode 23 of the capacitor, a hydrogen barrier film 31, that is, an aluminum oxide (alumina, (Al₂O₃)) film, is formed. On the hydrogen barrier film 31, a silicon oxide film 32 using TEOS is formed. When a silicon oxide film 32 is formed by CVD, hydrogen contained in the film-formation atmosphere is diffused into the ferroelectric film 22, degrading the performance of a capacitor due to a reduction ability of hydrogen. The hydrogen barrier film 31 suppresses such hydrogen diffusion. Another hydrogen barrier film 33, an Al₂O₃ film, is formed so as to cover the periphery of a stacked structure of the ferroelectric film 22, top electrode 23, hydrogen barrier film 31, and silicon oxide film 32. On the hydrogen barrier film 33, a silicon oxide film 34 using TEOS is formed. The hydrogen barrier film 33 acts in the same manner as the hydrogen barrier film 31.

The ferroelectric memory of this embodiment further comprises an oxygen barrier film 41 in addition to the aforementioned structure. After pattering of the insulating film 15 etc. is performed by reactive ion etching (RIE), the oxygen barrier film 41 is formed so as to cover the entire periphery of a stacked layer structure of the insulating film 15 and the capacitor (bottom electrode 21, ferroelectric film 22, and top electrode 23), etc.

The oxygen barrier film 41 has lower oxygen permeability than the insulating film (silicon oxide film) 15. More specifically, as compared the oxygen permeability per unit thickness, the oxygen permeability of the oxygen barrier film 41 is lower than that of the insulating film 15. As the oxygen barrier film 41, use is made of a silicon nitride (SiN) film, silicon oxynitride (SiON) film, aluminium oxide (Al₂O₃) film or a titanium oxide (TiO₂) film. Alternatively, a stacked layer of these films may be used as the oxygen barrier film 41. The silicon nitride film and silicon oxynitride film may be formed by CVD such as plasma CVD or LPCVD.

As described, in the embodiment, the entire stacked structure of the insulating film 15 and the capacitor, etc., is covered with the oxygen barrier film 41. Therefore, it is possible to suppress oxygen from entering the insulating film 15 when the structure of FIG. 1 is subjected to an annealing step performed in an atmosphere containing oxygen. As a result, oxidization of the plug 16 during the annealing step can be prevented. Therefore, the resistance of the plug and contact resistance thereof can be suppressed, providing a ferroelectric memory excellent in characteristics and reliability. For example, if the plug 16 is formed of tungsten (W) or polysilicon, the plug 16 is more severely damaged by oxidization. Therefore, the aforementioned structure more effectively works.

In this embodiment, the oxygen barrier film 14 is formed under the insulating film 15. On the other hand, the bottom electrode 21 of an Ir film or an IrO₂ film acting as an effective barrier to oxygen, is formed on the insulating film 15 and the plug 16. Since oxygen diffusion into the plug 16 is more effectively suppressed, oxidization of the plug 16 can be more efficiently prevented.

FIG. 2 is a sectional view showing the structure of a semiconductor device according to a modified example of this embodiment.

The structure of the semiconductor device is substantially the same as in FIG. 1 except that a hydrogen barrier film 42 covering the entire stacked film is formed between the oxygen barrier film 41 and the stacked film. The hydrogen barrier film 42 is desirably formed of a film having lower hydrogen permeability than the insulating film (silicon oxide film) 15, for example, an Al₂O₃ film.

When a silicon nitride film or a silicon oxynitride film used as the oxygen barrier film 41 is formed by plasma CVD or LPCVD, hydrogen contained in the film-formation atmosphere is diffused into the ferroelectric film 22. As a result, the performance of a capacitor decreases. Although Al₂O₃ films 31 and 33 have already been formed as hydrogen barrier films, hydrogen may enter the capacitor through the insulating film 15 when the oxygen barrier film 41 is formed. Since the hydrogen barrier film 42 is provided in this embodiment, hydrogen can be more efficiently suppressed from diffusing into the capacitor at the time the oxygen barrier film 41 is formed.

(Embodiment 2)

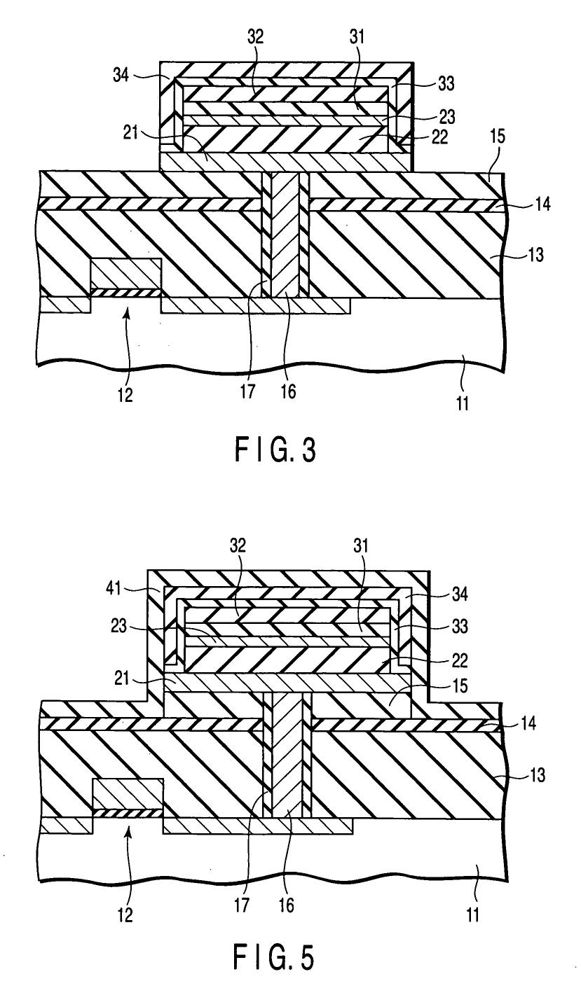

FIG. 3 is a schematic sectional view showing the structure of a semiconductor device, which is a ferroelectric memory having a COP structure, according to a second embodiment of the present invention. Like reference numerals are used in FIG. 3 to designate like structural elements corresponding to those like in FIG. 1 and any further explanation is omitted for brevity's sake.

In this embodiment, an oxygen barrier film 17 is provided around the plug 16. More specifically, the oxygen barrier film 17 is provided between the plug 16 and a stacked structure of the interlayer insulating film 13 (silicon oxide film), oxygen barrier film 14, and insulating film 15 (silicon oxide film). The oxygen barrier film 17, similarly to the oxygen barrier film 41 (described in the first embodiment), has lower oxygen permeability than the insulating film (silicon oxide film) 15. More specifically, as compared the oxygen permeability per unit thickness, the oxygen barrier film 17 is low in oxygen permeability than the insulating film 15. More specifically, as the oxygen barrier film 17, use is made of a silicon nitride (SiN) film, silicon oxynitride (SiON) film, aluminium oxide (Al₂O₃) film, or titanium oxide (TiO₂) film. Alternatively, the stacked layer of these films may be used as the oxygen barrier film 17. The silicon nitride film and silicon oxynitride film may be formed by CVD such as plasma CVD or LPCVD.

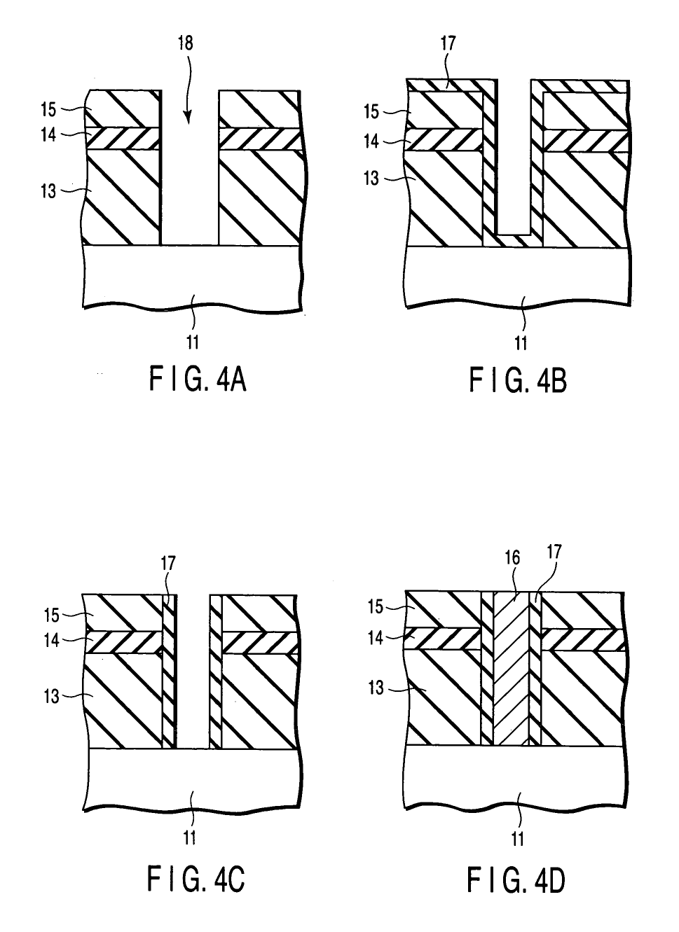

FIGS. 4A to 4D are schematic sectional views showing a method of forming the plug 16 and oxygen barrier film 17 shown in FIG. 3.

As shown in FIG. 4A, a contact hole 18 is formed by RIE through the interlayer insulating film 13, oxygen barrier film 14 and insulating film 15. Subsequently, as shown in FIG. 4B, the oxygen barrier film 17 is formed over the entire surface including the inner surface of the contact hole 18 by CVD. Subsequently, as shown in FIG. 4C, the oxygen barrier film 17 is etched back to leave the oxygen barrier film 17 on the sidewall of the contact hole 18. Thereafter, as shown in FIG. 4D, a plug material using a conductive material such as tungsten (W) or polysilicon is formed over the entire surface including the contact hole 18. Excess plug material is removed by chemical mechanical polishing (CMP) to form the plug 16 in the contact hole 18.

In this embodiment, an oxygen barrier film 17 is formed around the plug 16. Therefore, when the structure shown in FIG. 3 is subjected to annealing in an atmosphere containing oxygen, the oxygen barrier film 17 can block oxygen diffusing from the insulating film 15 to the plug 16. Since oxygen is prevented from entering the plug 16, oxidization of the plug 16 during the annealing step can be prevented, suppressing the resistance of the plug and contact resistance thereof from increasing. As a result, a ferroelectric memory excellent in characteristics and reliability can be obtained.

(Third Embodiment)

FIG. 5 is a schematic sectional view showing a semiconductor device (ferroelectric memory having a COP structure) according to a third embodiment of the present invention.

This structure of this embodiment is substantially the same as in the first and second embodiments except that both the oxygen barrier film 41 (explained in the first embodiment) and the oxygen barrier film 17 (explained in the second embodiment) are provided. Since the basic structure of this embodiment is the same as those of the first and second embodiments and further explanation thereof is omitted. The structure of FIG. 5 corresponds to the combined structure of FIGS. 1 and 3. Alternatively, the structure of FIG. 2 may be combined with that of FIG. 3. More specifically, a hydrogen barrier film 42 shown in FIG. 2 may be provided inside the oxygen barrier film 41.

In this embodiment, oxygen can be more efficiently suppressed from entering the plug 16 by providing the oxygen barrier films 41 and 17. As a result, a ferroelectric memory excellent in characteristics and reliability can be obtained.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor device comprising:
an insulating film;
a capacitor formed on the insulating film and comprising a bottom electrode, a top electrode, and a dielectric film between the top electrode and the bottom electrode;
a plug passing through the insulating film and connected to the bottom electrode; and
an oxygen barrier film covering the capacitor and the insulating film, and having lower oxygen permeability than the insulating film.

2. The semiconductor device according to claim 1, further comprising a film provided under the insulating film and having lower oxygen permeability than the insulating film.

3. The semiconductor device according to claim 1, further comprising a hydrogen barrier film covering the capacitor and the insulating film, formed inside the oxygen barrier film and having lower hydrogen permeability than the insulating film.

4. The semiconductor device according to claim 1, further comprising a transistor electrically connected to the plug.

5. The semiconductor device according to claim 1, wherein the oxygen barrier film comprises at least one of a silicon nitride film, a silicon oxynitride film, an aluminum oxide film and a titanium oxide film.

6. The semiconductor device according to claim 1, wherein the plug is formed of tungsten or polysilicon.

7. The semiconductor device according to claim 1, wherein the bottom electrode contains iridium.

8. The semiconductor device according to claim 1, wherein the dielectric film comprises a ferroelectric film.

9. A semiconductor device comprising:
an insulating film;
a capacitor formed on the insulating film and comprising a bottom electrode, a top electrode, and a dielectric film between the top electrode and the bottom electrode;
a plug passing through the insulating film and connected to the bottom electrode; and
an oxygen barrier film formed between the insulating film and the plug, and having lower oxygen permeability than the insulating film.

10. The semiconductor device according to claim 9, further comprising a film provided under the insulating film and having lower oxygen permeability than the insulating film.

11. The semiconductor device according to claim 9, further comprising a transistor electrically connected to the plug.

12. The semiconductor device according to claim 9, wherein the oxygen barrier film comprises at least one of a silicon nitride film, a silicon oxynitride film, an aluminum oxide film and a titanium oxide film.

13. The semiconductor device according to claim 9, wherein the plug is formed of tungsten or polysilicon.

14. The semiconductor device according to claim 9, wherein the bottom electrode contains iridium.

15. The semiconductor device according to claim 9 wherein the dielectric film comprises a ferroelectric film.

16. A semiconductor device comprising:
an insulating film;
a capacitor formed on the insulating film and comprising a bottom electrode, a top electrode, and a dielectric film between the top electrode and the bottom electrode;
a plug passing through the insulating film and connected to the bottom electrode;
a first oxygen barrier film covering the capacitor and the insulating film, and having lower oxygen permeability than the insulating film; and
a second oxygen barrier film formed between the insulating film and the plug, and having lower oxygen permeability than the insulating film.
